(19) United States
(12) Patent Application Publication
(10) Pub. No.: US 2007/0098526 A1
(43) Pub. Date: May 3, 2007

(54) Substrate transportation system

(75) Inventor: Yasushi Naito, Tokyo (JP)

Correspondence Address: BUCHANAN, INGERSOLL & ROONEY PC, POST OFFICE BOX 1404, ALEXANDRIA, VA, 22313-1404, US

(73) Assignee: Hirata Corporation

(21) Appl. No.: 11/641,653

(22) Filed: Dec. 20, 2006

Related U.S. Application Data
(62) Division of application No. 11/236,803, filed on Sep. 28, 2005.

(30) Foreign Application Priority Data
Mar. 28, 2003 (JP) 2003-091793
Mar. 23, 2004 (WO) PCT/JP04/03958

(51) Int. Cl. H01L 21/677

(52) U.S. Cl. 414/217

(57) ABSTRACT

A versatile substrate transportation system is provided which can cope with various processing devices with high degrees of freedom. For this purpose, a tunnel (101) is arranged to connect a plurality of processing devices (102). The tunnel (101) and processing devices (102) are not directly connected but via interface devices (103). That is, the tunnel (101) is connected at its lower surface to the interface device (103), and the interface device (103) is connected at its side surface to the processing device (102). The interface device (103) is arranged below the tunnel (101) at a height corresponding to a substrate reception port of the processing device (102).

### CROSS REFERENCE TO RELATED APPLICATION

This application is a divisional application of application Ser. No. 11/236,803, filed Sep. 28, 2005.

### TECHNICAL FIELD

The present invention relates to a substrate transportation system for transporting a substrate to a processing device.

### BACKGROUND ART

Conventionally, a substrate transportation system which transports a substrate to a processing device is known. Particularly, a system is known well which stores a plurality of substrates in a substrate storing cassette called an FOUP and transports the substrates in the cassette as a batch (for example, see Japanese Patent Laid-Open No. 06-016206).

In the conventional system which transports the plurality of cassettes in the cassette at once as a batch, when the substrate size is large, the risk concerning accidents during transportation increases. Also, the system scale increases, and accordingly the system is not appropriate for many-product-type, small-lot production.

### DISCLOSURE OF INVENTION

The present invention has been made to solve the problems of the above prior art, and has as its object to provide a versatile substrate transportation system which can cope with various types of processing devices with higher degrees of freedom.

In order to achieve the above object, according to the present invention, there is provided a substrate transportation system including a tunnel which transports a substrate one by one and an interface device which delivers the substrate between the tunnel and a processing device, characterized in that the interface device can cope with a plurality of types of processing devices.

In order to achieve the above object, according to the present invention, there is provided another substrate transportation system including a tunnel which transports a substrate one by one and an interface device which delivers the substrate between the tunnel and a processing device, characterized in that the interface device is arranged under the tunnel and has means for delivering the substrate vertically to and from the tunnel.

The interface device is characterized by including substrate moving means capable of moving the substrate vertically to substrate loading ports of the plurality of types of processing devices. The interface device is characterized by detachably including a hand to load the substrate to substrate loading ports of the plurality of types of processing devices. The interface device is characterized by having a substrate loading port from the tunnel and a substrate unloading port to the processing device, including openable/closeable doors at the substrate loading port and substrate unloading port, and having a chamber function. The interface device is characterized by including first transporting means for delivering the substrate from the tunnel to the processing device, and second transporting means for delivering the substrate from the processing device to the tunnel. The substrate transportation system is characterized by comprising buffer means for buffering vibration between the tunnel and interface device. The tunnel is characterized by having a window portion. The interface device is characterized by including direction adjusting means for adjusting a direction of the substrate to be delivered to the processing device. The interface device is characterized by including information reading means for reading information added to the substrate. The interface device is characterized by including transporting means capable of transporting the substrate in two directions to load the substrate to substrate loading ports of the processing devices on the two sides when the processing devices are provided on two sides of the interface device. The substrate transportation system is characterized by including a plurality of interface devices each of which delivers the substrate to and from a corresponding processing device, and in that the plurality of interface devices include delivery means for delivering the substrate to and from the processing device arranged on one side of the tunnel.

Other features and advantages of the present invention will be apparent from the following description taken in conjunction with the accompanying drawings, in which like reference characters designate the same or similar parts throughout the figures thereof.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1A is a perspective view showing the appearance of a substrate transportation system according to the first embodiment of the present invention;

FIG. 1B is a view showing the arrangement of interface devices according to the first embodiment of the present invention;

FIGS. 2A and 2B are views showing the internal structures of a tunnel and interface device according to the first embodiment of the present invention;

FIGS. 3A and 3B are views each showing a connecting portion between the tunnel and interface device according to the first embodiment of the present invention;

FIG. 3C is a perspective view showing the internal structure of the tunnel according to the first embodiment of the present invention;

FIGS. 4A and 4B are views showing the structure of a substrate transport car according to the first embodiment of the present invention;

FIG. 5 includes views for explaining the substrate delivery operation of a substrate transportation system according to the first embodiment of the present invention;

FIG. 6 includes views for explaining the substrate delivery operation of the substrate transportation system according to the first embodiment of the present invention;

FIGS. 7A and 7B are views showing another example of an interface device according to the present invention;

FIG. 8A is a view for explaining the entire layout of the substrate transportation system according to the first embodiment of the present invention;

FIG. 8B is a view for explaining the entire layout of the substrate transportation system according to the first embodiment of the present invention;

FIGS. 9A to 9E are views showing various layout patterns of the tunnel and processing device according to the first embodiment of the present invention;

FIG. 10 is a plan view showing the internal structure of a transfer device which does not have a substrate storing function;

FIG. 11A is a plan view showing the internal structure of a transfer device which has a substrate storing function;

FIG. 11B is a side sectional view showing the internal structure of the transfer device which has the substrate storing function;

FIGS. 11C and 11D are views showing another example of a transfer device which has a substrate storing function;

FIG. 12A is a plan view showing the internal structure of a transfer device which has reading devices;

FIG. 12B is a side sectional view showing the internal structure of the transfer device which has the reading devices;

FIG. 13 is a view for explaining the structure and operation of an interface device according to the second embodiment of the present invention;

FIG. 14 is a view for explaining the structure and operation of the interface device according to the second embodiment of the present invention;

FIG. 15 is a view for explaining the structure and operation of the interface device according to the second embodiment of the present invention;

FIG. 16 is a view for explaining the structure and operation of the interface device according to the second embodiment of the present invention;

FIG. 17 is a view for explaining the structure and operation of the interface device according to the second embodiment of the present invention;

FIG. 18 is a view for explaining the structure and operation of the interface device according to the second embodiment of the present invention;

FIG. 19 is a view showing a modification of the interface device according to the second embodiment of the present invention;

FIGS. 20A and 20B are schematic views showing the internal structure of a tunnel according to the third embodiment of the present invention;

FIG. 21 is a schematic view showing the internal structure of a tunnel and interface device according to the fourth embodiment of the present invention;

FIGS. 22A to 22E are views for explaining rail switching operation in a tunnel according to the fifth embodiment of the present invention;

FIGS. 23A and 23B are views for explaining a rail slide mechanism in the tunnel according to the fifth embodiment of the present invention;

FIGS. 24A to 24D are views each showing the layout in the tunnel according to still other embodiments of the present invention; and

FIGS. 25A to 25C are views showing the examples of the distal end shapes of arms according to still other embodiments of the present invention.

### BEST MODE FOR CARRYING OUT THE INVENTION

Preferred embodiments of the present invention will now be exemplarily described in detail in accordance with the accompanying drawings. Note that the relative positions and the like of the constituent elements described in the embodiments are merely examples, and the scope of the present invention is not limited to them unless otherwise specified.

### First Embodiment

(Structure)

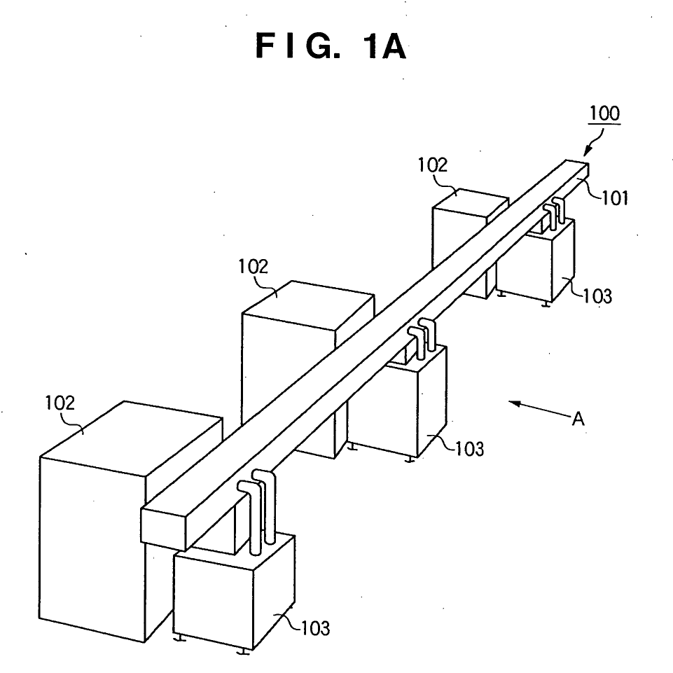

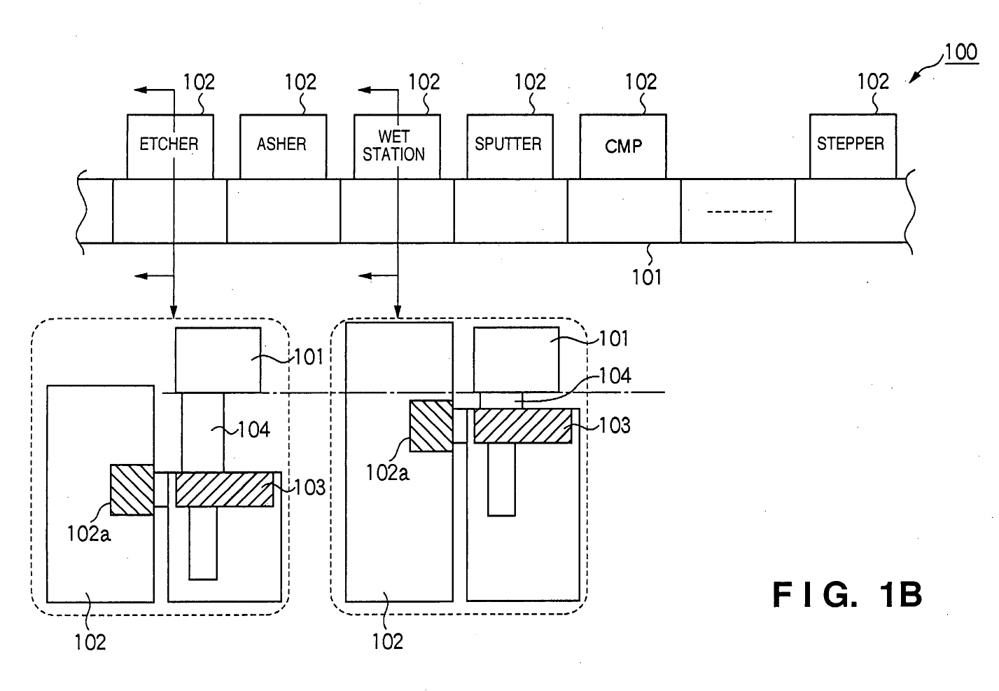

FIG. 1A is a schematic view showing the layout of part of a substrate transportation system 100 according to the first embodiment of the present invention.

Referring to FIG. 1A, reference numeral 101 denotes a tunnel; 102, processing devices which process substrates; and 103, interface devices which deliver the substrates between the tunnel 101 and processing devices 102.

The tunnel 101 is provided so as to connect the plurality of processing devices 102. The tunnel 101 and processing devices 102 are connected not directly but via the interface devices 103. More specifically, the tunnel 101 is connected at its lower surface to each interface device 103, and each interface device 103 is connected at its side surface to the corresponding processing device 102. The tunnel 101 forms units each having a width almost coinciding with the width of the corresponding interface device 103. Each unit can be removed for maintenance. The combination of the tunnel 101 and interface device 103 can be handled as one unit. In this embodiment, the interface devices 103 are provided to the plurality of processing devices 102 in one-to-one correspondence.

A transport mechanism for transporting the substrate (wafer) is arranged in the tunnel 101. The substrate transported in the tunnel is transferred to the interface device 103 and then transported from the interface device 103 to the processing device 102.

FIG. 1B is a view showing the layout of the substrate transportation system 100 from another angle. The upper side of FIG. 1B includes a view showing the substrate transportation system 100 from above, and the lower side of FIG. 1B includes a schematic sectional view showing the same from the longitudinal direction of the tunnel.

For example, when a series of processing devices 102, e.g., an etcher, asher, wet station, sputter, CMP, stepper, and the like which are necessary for completing a wafer are arranged along the tunnel 101, as in the view on the upper side of FIG. 1B, substrate delivery portions 102a of the respective processing devices 102 may have different heights. As the height of the tunnel 101 is basically constant, the lengths of communicating portions 104 between the tunnel 101 and interface devices 103 are changed in accordance with the processing devices 102, and the interface devices 103 are set at heights in accordance with the processing devices 102. More specifically, for a processing device 102 having a comparatively low substrate delivery portion 102a, the interface device 103 is set low, as shown in the lower left view of FIG. 1B. For a processing device 102 having a comparatively high substrate delivery portion 102a, the interface device 103 is set high, as shown in the lower right view of FIG. 1B. Thus, the interface devices of one type can cope with a plurality of types of processing devices. While an explanation will be made specifically on transportation of the substrates, the transportation mechanism of this system 100 can transport not only ordinary wafers but also other types of wafers such as a reticle, monitor wafer, dummy wafer, and the like that are mixed. In this case, a controller is preferably provided which synthetically controls transportation of the substrates and reticles in the tunnel. This controller synthetically controls transportation of the substrate transport cars and interface devices so that, e.g., when the type of wafers to be manufactured or the processing conditions for the wafers are changed, a reticle in a reticle storing portion that matches the conditions is placed on the transport car and transported to a predetermined processing device, e.g., a stepper, in which the reticle need be changed, and that the reticle is loaded in the predetermined processing device that requires the reticle.

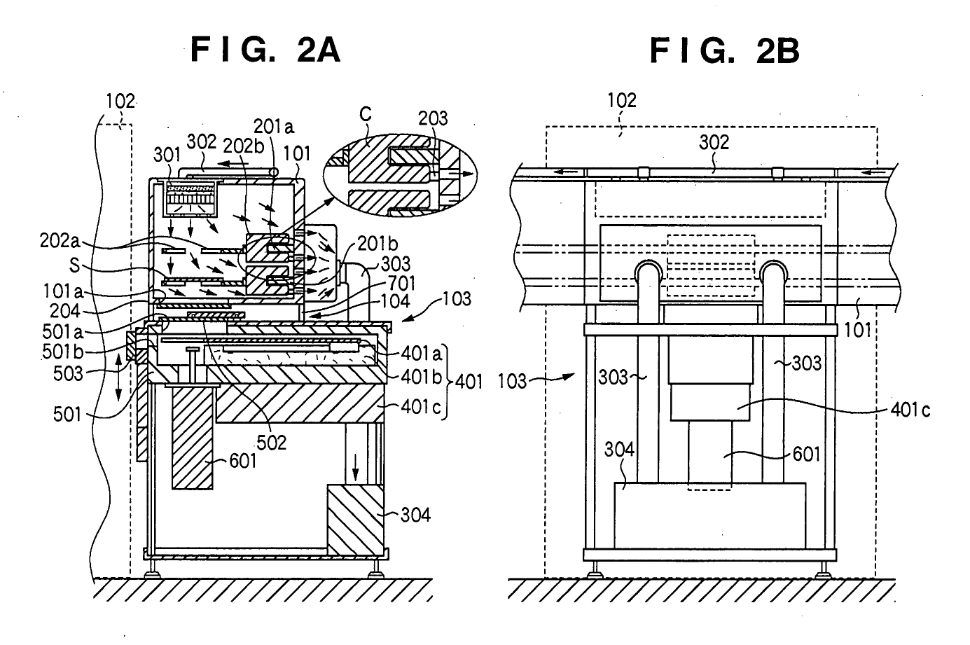

FIG. 2A is a schematic view showing the interior of the tunnel 101 and that of the interface device 103. FIG. 2B is a view showing the outer appearance of the tunnel 101 and interface device 103 seen from a side A of FIG. 1A in the direction of arrow.

As shown in FIG. 2A, two rails 201a and 201b are provided to the inner side wall of the tunnel 101 to be parallel to each other in the vertical direction. Each of the two rails 201a and 201b can support a plurality of substrate transport cars 202. The substrate transport cars 202 are driven by motors to travel along the rail 201a or 201b in a self-propelled manner. Hence, the tunnel 101 has in it the first transport path which transports the substrates and the second transport path which transports the substrates above the first transport path.

Each substrate transport car 202 includes a C-shaped tray 202a on which a substrate S can be placed and a cart 202b which travels along a rail 201 while supporting the tray 202a.

C of FIG. 2A is an enlarged view of a portion near the base of the rail 201. As shown in C, feeding elements 203 are provided to part of the inner side surface of the tunnel 101. The feeding elements 203 are arranged at positions where the substrate transport cars 202 stop to load or unload the substrates to and from the processing devices 102. While stopping, each substrate transport car 202 comes into contact with the corresponding feeding element 203 to receive power to a battery (not shown) in the substrate transport car 202. The motor is driven by the power accumulated in the battery so that the substrate transport car 202 travels on the rail.

Cleaning units 301 each including an air clean filter (ULPA (Ultra Low Penetration Air) filter) are provided in the tunnel 101. Each cleaning unit 301 is connected to a pipe 302. Air flowing into the cleaning unit 301 through the pipe 302 is cleaned as it passes through the air cleaning filter of the cleaning unit 301, flows in the tunnel 101, as indicated by arrows, and is supplied to an air discharge unit 304 through exhaust ducts 303. According to this embodiment, the pipe 302 is connected to cover the respective units of the tunnel 101, as shown in FIG. 2B. More specifically, the substrate transportation system 100 has a large air supply unit (not shown). The pipe 302 is laid to extend from the air supply unit along the tunnel 101, and branches midway to be connected to the cleaning units 301 provided to the respective units of the tunnel 101.

Thus, the interior of the tunnel 101 is constantly filled with clean air to prevent dust or the like from attaching to the substrate to be transported. The cleaning units 301 can be removed for maintenance. Although the ULPA filter is provided to each cleaning unit 301 in this embodiment, the present invention is not limited to this. A clean filter such as an HEPA (High Efficiency Particulate Air) filter may be provided to comply with a predetermined cleanliness.

The bottom surface of the tunnel 101 has an opening 101a through which the substrate is unloaded to and loaded from the interface device 103. A shutter 204 is provided to open/close the opening 101a.

In the communicating portion 104, a shield wall 701 is provided for the purpose of ensuring predetermined sealing properties so that when the substrate is to be delivered between the tunnel 101 and interface device 103, dust or the like will not attach to the substrate. The shield wall 701 can have a buffering function so vibration will not be transmitted between the tunnel 101 and interface device 103. In this case, for example, the shield wall 701 can be a freely stretchable member such as a bellows member.

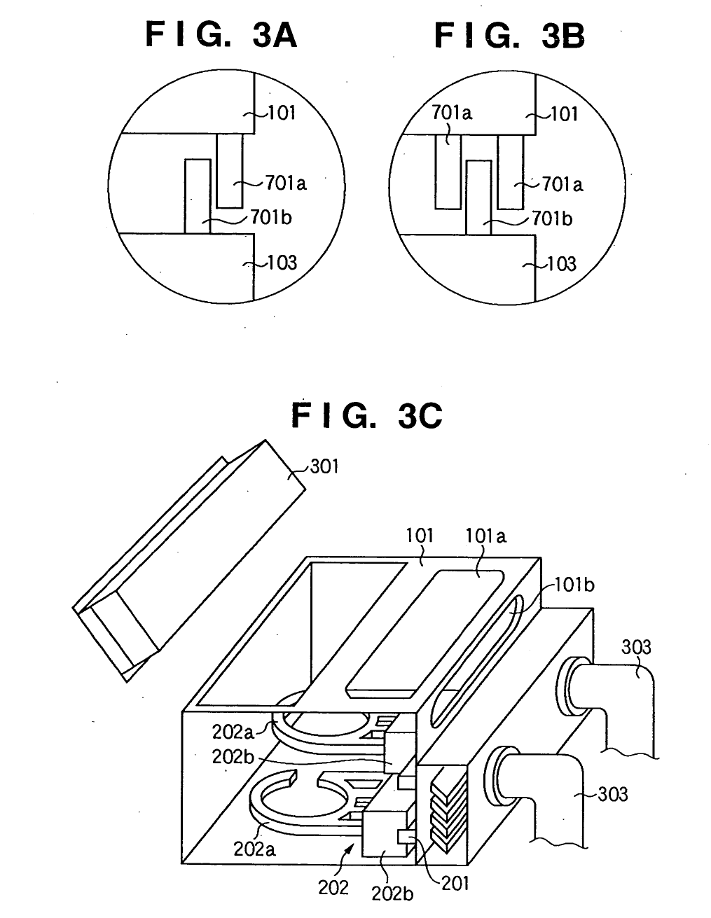

The arrangement of the shield wall 701 is not limited to one that allows the tunnel 101 and interface device 103 to communicate with each other. For example, as shown in FIGS. 3A and 3B, projection walls 701a and 701b that do not come into contact with each other may be respectively provided to the lower portion of the tunnel 101 and the upper portion of the interface device 103 to surround the substrate delivery opening, thus forming a labyrinth structure. At this time, if the internal pressure between the tunnel 101 and interface device 103 is set higher than the outside, dust or the like will not attach to the substrate.

The interface device 103 is arranged below the tunnel 101 at a height corresponding to the substrate reception port of the processing device 102. The interface device 103 includes a chamber 501 which can form a sealed space, a slide unit 401 which transports the substrate within the chamber 501, and a substrate elevating unit 601 which transfers the substrate from the substrate transport car 202 to the slide unit 401. In other words, the substrate elevating unit 601 has the function of delivering the substrate to and from the tunnel 101 in the vertical direction.

The chamber 501 has an opening 501a on the tunnel 101 side and an opening 501b on the process side, which can be opened and closed respectively by gate valves 502 and 503 serving as opening/closing doors.

The slide unit 401 includes a slide arm 401a, slide table 401b, and slider drive 401c. When the slider drive 401c transmits power to the slide table 401b, the slide arm 401a attached to the slide unit 401 moves back and forth with respect to the processing device 102. Thus, the substrate placed on the slide arm 401a is slid to the left in FIG. 2A and transported into the processing device 102.

FIG. 3C is a perspective view showing the interior of the tunnel 101. As shown in FIG. 3C, the cleaning unit 301 can be removed for exchange or maintenance. The window 101a and a window 101b fitted with transparent plates are formed in the ceiling and side surface of the tunnel 101, so that the interior of the tunnel 101 can be seen. Thus, the state of the substrate in the tunnel or a trouble occurring in the tunnel can be found instantaneously.

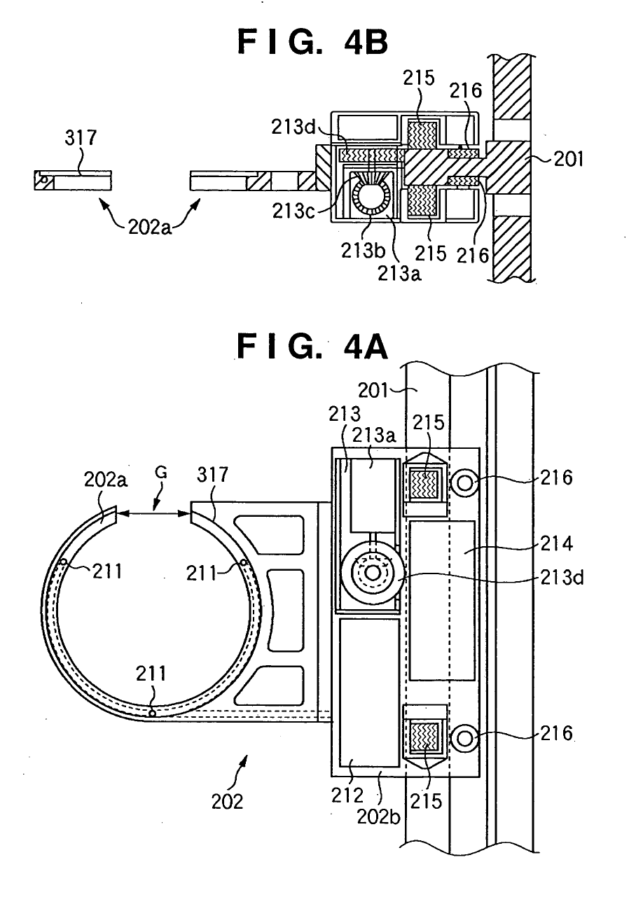

FIGS. 4A and 4B are schematic views showing the internal structure of the substrate transport car 202.

FIG. 4A shows the internal structure of the substrate transport car 202 seen from above. FIG. 4B shows the internal structure of the substrate transport car 202 seen from a lower portion in FIG. 4A. As shown in FIG. 4A, the tray 202a is C-shaped and has a gap G in part of its periphery. Three chucking ports 211 for chucking and holding the substrate are formed in the upper surface of the tray 202a. All the chucking ports 211 are connected to a pump unit 212 in the cart 202b.

With the substrate being placed on the tray 202a, when the pump unit 212 is driven to take air in from the chucking ports 211, the substrate is chucked to the tray 202a. The tray 202a also has a groove 317 to place the substrate. When the substrate is fitted in the groove 317 and drawn by suction through the chucking ports 211, the substrate is fixed without being shifted or dropping during transportation.

The cart 202b includes, in addition to the pump unit 212, a driving unit 213 which causes the cart 202b to travel and a control unit 214 which controls the pump unit 212 and driving unit 213.

The driving unit 213 includes in it a motor 213a, gears 213b and 213c, and a driving roller 213d. When the rotation force of the motor 213a is transmitted to the driving roller 213d through the gears 213b and 213c to rotate the driving roller 213d which is in slidable contact with the rail 201, the cart 202b travels on the rail 201.

The cart 202b includes, in addition to the driving roller 213d, guide rollers 215 to clamp the rail 201 in the vertical direction and guide rollers 216 to horizontally clamp the rail 201 together with the driving roller 213d. With these guide rollers, the cart 202b can stably travel on the rail 201.

(Substrate Delivery Operation)

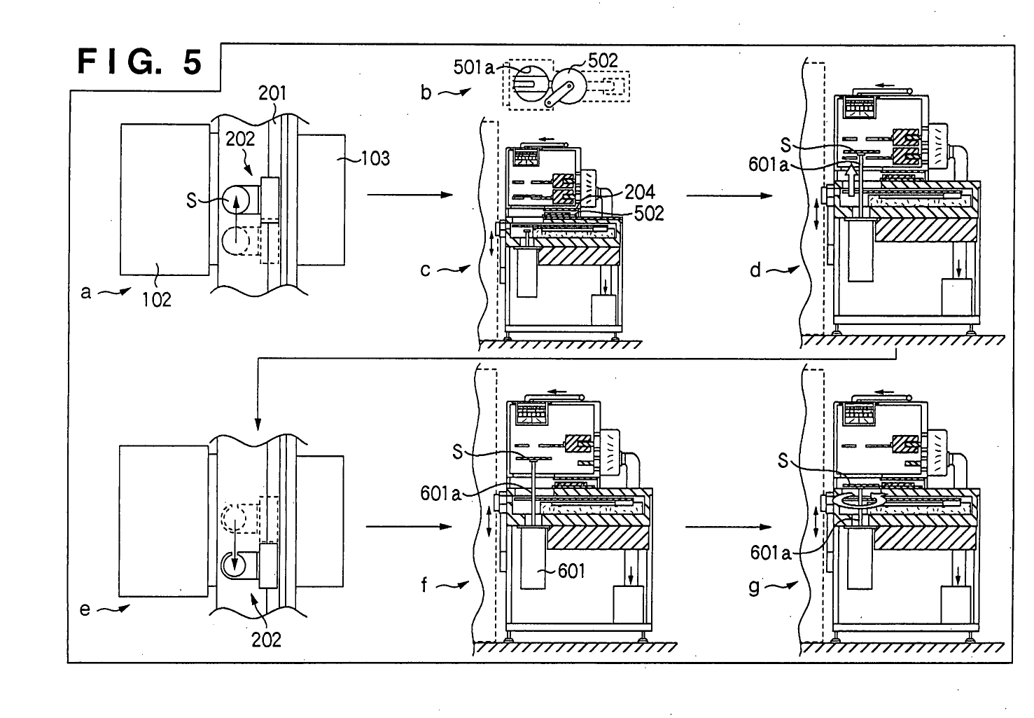

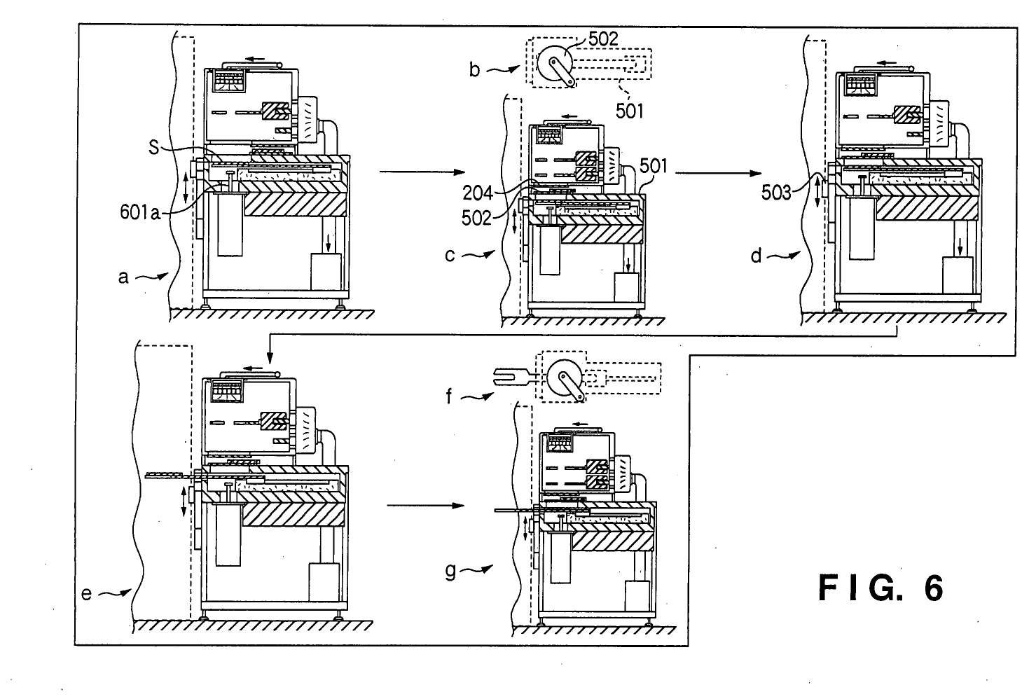

The substrate delivery operation will be described with reference to FIGS. 5 and 6. Each of a and e of FIG. 5 shows the position of the substrate transport car 202 in the tunnel 101 seen from above the tunnel through the ceiling portion of the tunnel 101. Each of b of FIG. 5 and b and f of FIG. 6 shows the partial appearance of the interface device 103 seen from the tunnel 101 side. Each of c, d, f, and g of FIG. 5 and of a, c, d, e, and g of FIG. 6 shows the interiors of the tunnel 101 and interface device 103 in the same manner as in FIG. 2A.

First, as shown in a of FIG. 5, the substrate transport car 202 on which the substrate S is placed travels along the rail 201 and stops above the interface device 103.

Subsequently, as shown in b and c of FIG. 5, the shutter 204 in the lower portion of the tunnel 101 and the gate valve 502 in the upper portion of the interface open. A support shaft provided to the upper surface of the interface device 103 is connected to the center shaft of the disk-like gate valve 502 through an arm. When opening operation is performed to pivot the arm about the support shaft as the center, the gate valve 502 moves from the position to close the opening 501a to the position to open it.

When the gate valve 502 and shutter 204 are opened, as shown in d, the substrate elevating unit 601 operates to move a push-up rod 601a upward so as to push up the substrate S on the tray 202a.

When the push-up operation of the substrate S is completed, as shown in e, the substrate transport car 202 moves toward a portion (downward in FIG. 5) where the gap G is not present. In other words, the substrate transport car 202 is moved such that the push-up rod 601a extends through the gap G.

When the substrate transport car 202 completely retreats from the substrate delivery position, as shown in f, the substrate elevating unit 601 operates to move the push-up rod 601a downward with the substrate S being placed on it.

As shown in g, the push-up rod 601a is stopped temporarily near the top plate of the interface device 103. The push-up rod 601a is rotated to align the orientation fracture of the substrate S. Orientation fracture alignment means to set a fracture portion formed in part of the substrate S in a predetermined direction. Depending on the type of the processing device 102, sometimes the substrate needs to be loaded such that it is set in a predetermined direction. When the substrate is to be loaded in such a processing device 102, the substrate elevating unit 601 serves as a direction adjusting means for adjusting the direction of the substrate. More specifically, an optical sensor (not shown) provided to the upper surface of the top plate of the interface device 103 detects the fracture portion of the substrate S.

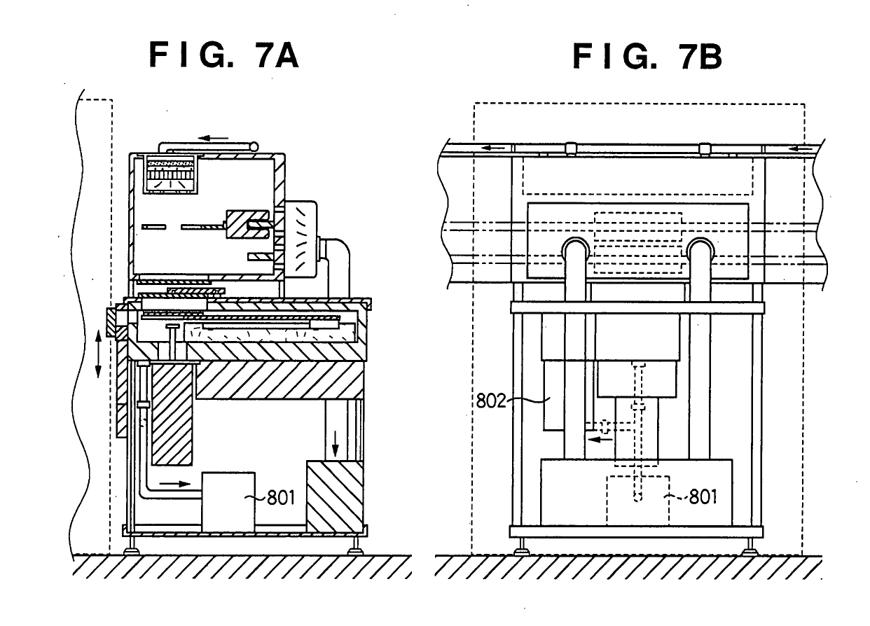

When the orientation fracture alignment is ended, the push-up rod 601a is further moved downward, as shown in a of FIG. 6, to place the substrate S on the slide arm 401a. In this state, the shutter 204 in the lower portion of the tunnel 101 and the gate valve 502 on the upper portion of the interface device 103 move to the closing positions, as shown in b and c. Depending on the type of the processing device 102, it is checked that the gate valve 502 of the interface device 103 is closed completely. After that, the interior of the chamber 501 of the interface device 103 is pressure-reduced. More specifically, if the processing device 102 is of a type that performs the process under a low pressure, the pressure in the chamber 501 is decreased accordingly. If, for example, the processing device 102 is of a type that performs the process in a high vacuum, a low-vacuum pump 801 and high-vacuum pump 802 are further connected to the interface device 103, as shown in FIGS. 7A and 7B, to set a high vacuum state in the chamber 501. When the processing device 102 requires a low vacuum, only the low-vacuum pump 801 needs to be connected to the interface device 103, as a matter of course.

When pressure reduction in the chamber 501 is completed, the gate valve 503 provided to the processing-side side surface of the interface device is opened, as shown in d of FIG. 6. The slider drive 401c is operated to slide the slide arm 401a attached to the slide table 401b toward the processing device 102, as shown in e.

In this state, the processing device 102 receives the substrate S placed on the fork-like distal end portion of the slide arm 401a, and is set in the states of f and g. After that, the slide arm 401a is retreated into the chamber 501 to return to the position of d. When the process for the substrate is completed in the processing device 102, the slide arm 401a is slid again and stands by in the states of f and g. On the processing device 102 side, when the substrate S is placed on the slide arm 401a and set in the state of e, the state sequentially changes in the order of d of FIG. 6→b & c of FIG. 6→a of FIG. 6→f of FIG. 5→d of FIG. 5→c of FIG. 5.

More specifically, the slide arm 401a retreats to load the substrate S in the chamber 501 (d of FIG. 6). The gate valve 503 is closed to restore the pressure in the chamber 501 to the atmospheric pressure (c of FIG. 6). After that, a substrate unloading request is sent to the substrate transport car 202. The substrate transport car 202 is made to stand by before the substrate receiving position above the interface device 103, and the shutter 204 and gate valve 502 open (a of FIG. 6). Subsequently, the push-up rod 601a moves upward to push up the substrate S on the slide arm 401a, moves further upward, and stops (f of FIG. 5). The substrate transport car 202 which has been standing by at the standby position moves so that the push-up rod 601a extends through the gap G, and then stands by at the receiving position (d of FIG. 5). The push-up rod 601a moves downward to transfer the substrate S onto the tray 202a of the substrate transport car 202. After the downward movement of the push-up rod 601a is completed, the substrate transport car 202 transports the substrate S to the next processing device. Simultaneously, the shutter 204 and gate valve 502 are closed.

(Overall Layout)

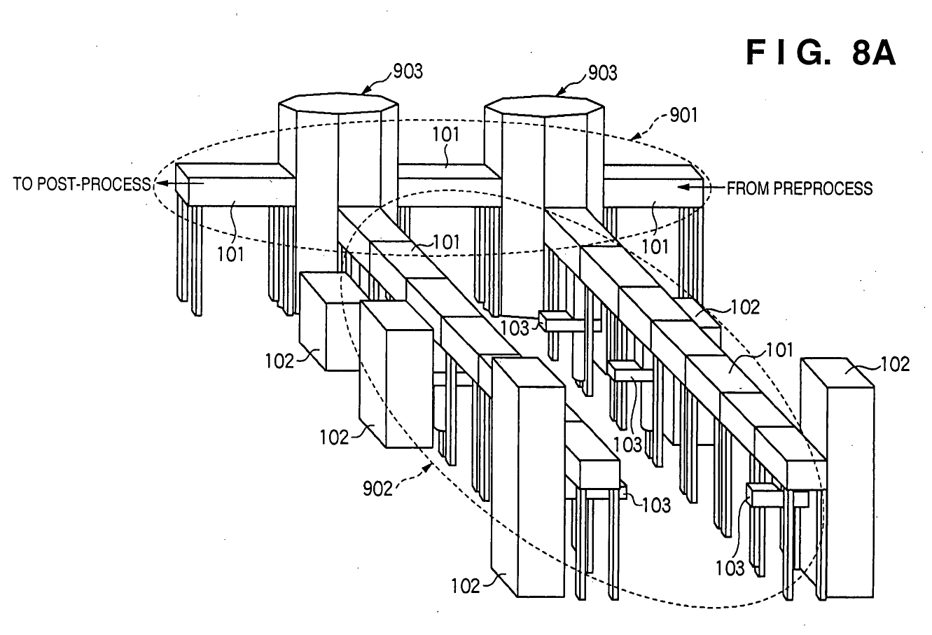

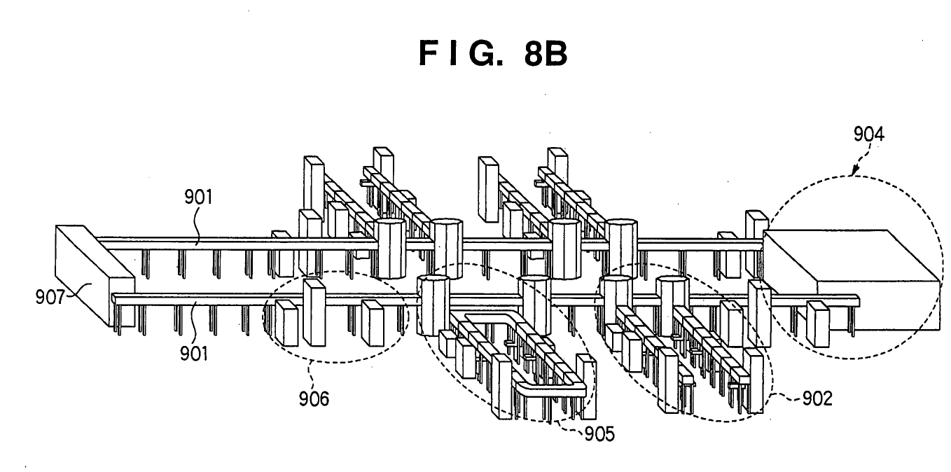

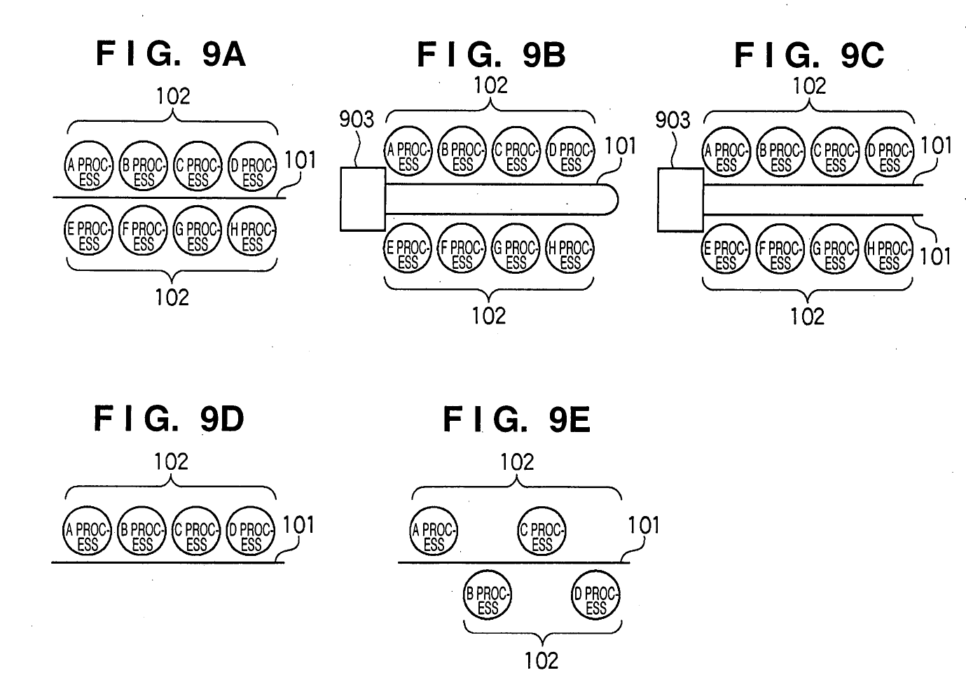

The overall layout of the substrate transportation system 100 will be described with reference to FIGS. 8A and 8B and FIGS. 9A to 9E.

FIG. 8A is a view showing the relationship between the main transport path and sub-transport paths. The substrate transportation system 100 includes a main transport path 901 and sub-transport path 902. The tunnel 101 of the main transport path 901 is connected to the tunnels 101 of the sub-transport path 902 through transfer devices 903. The transfer device 903 is a device that transfers the substrate transported in the tunnel 101 of the main transport path 901 to the tunnel 101 of the sub-transport path 902. The tunnels 101 included in the sub-transport path 902 are linear and have dead ends. Thus, the substrate transferred from the main transport path 901 to the sub-transport path 902 is processed by the processing devices 102 while it reciprocates in the tunnels 101 of the sub-transport path 902. During this operation, the substrate is transported from the tunnel 101 to the processing devices 102 by the interface devices 103.

The substrate which has been processed in the sub-transport path 902 is transferred to the main transport path 901 again and sent to the next step.

FIG. 8B is a view showing a further overall layout example of the substrate transport system. The system shown in FIG. 8B has two main transport paths 901, each of which is connected to sub-transport paths 902 and 905. A container warehouse 904 is connected to the ends of the main transport paths 901. The container warehouse 905 stores containers, each containing substrates, sent from the substrate manufacturing factory, and extracts the substrates one by one from the containers and loads them in the main transport paths 901.

Each sub-transport path 902 has a linear layout in the same manner as that described with reference to FIG. 8A. Each sub-transport path 905 has an endless tunnel 101. The substrates are transported in the sub-transport path 905 in one direction so that they can be subjected to one process over and over again. Each main transport path 901 is connected to a processing device group 906 to which the substrates are transported directly not through a subtransport path. The substrates which are transported through the main transport paths 901 and subjected to a series of processes are gathered in a container accommodating device 907, accommodated in predetermined numbers in containers, and transported to another factory or a later step.

The shape of the tunnel 101 in the transport path and the arrangement of the processing device 102 will be described. FIGS. 9A to 9E are views showing various layout patterns of the tunnel 101 and processing device 102.

Of FIGS. 9A to 9E, FIG. 9A shows a layout in which processing devices 102 are arranged on the two sides of a transport path including one linear tunnel 101. To implement this layout, interface devices 103 (not shown) which transport the substrates from the tunnel 101 to the processing devices 102 must have the ability of transporting the substrates to the two sides of the tunnel. With this two-side arrangement, the area required for installing the plurality of processing devices becomes small as a whole. The space in the substrate processing factory can be used effectively to reduce the cost of the factory.

FIG. 9B shows a layout in which processing devices 102 are arranged on the two sides of a transport path including a loop-like tunnel 101. The transport path partly has a transfer device 903. The transfer device 903 can transport to the transport path again or store in the transfer devices 903 a substrate which has returned after being subjected to a series of processes. FIG. 9C shows a layout in which processing devices 102 are arranged on the two sides of a transport path including two linear tunnels 101. The transport path partly has a transfer device 903 in FIG. 9C as well. The transfer device 903 can transport a substrate, which has returned after being subjected to a series of processes in one tunnel 101, to the other tunnel 101. The respective processing devices 102 can be maintained easily from an aisle sandwiched by the tunnels 101 as well. FIG. 9D shows a layout in which processing devices 102 are arranged on one side of a transport path including one linear tunnel 101. FIG. 9E shows a layout in which processing devices 102 are arranged on the two sides of a transport path including a linear tunnel 101 alternately in a staggered manner across the tunnel 101.

(Structure of Transfer Device)

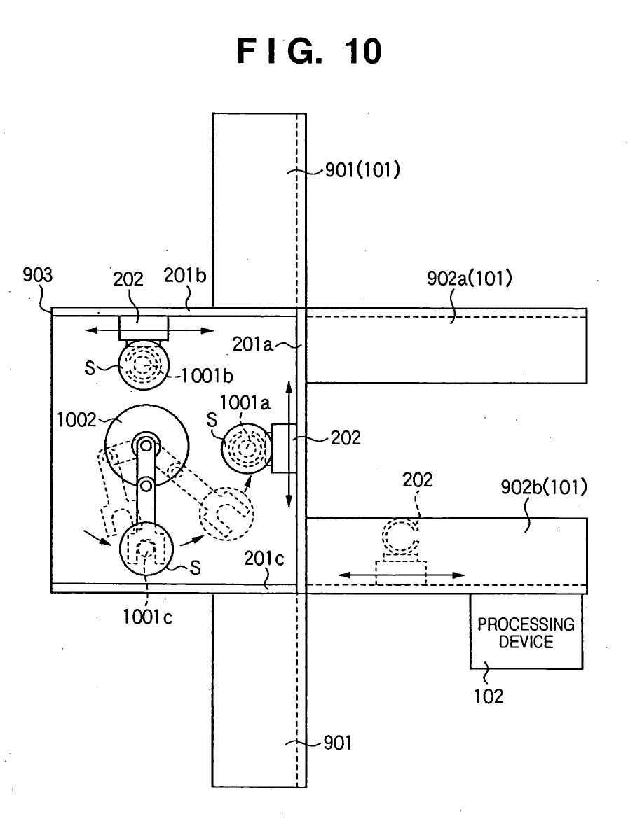

The internal structure of each of the transfer devices 903 shown in FIG. 8A will be described with reference to FIGS. 10 to 12B.

FIG. 10 is a plan view showing the internal structure of a transfer device 903 which does not have the function of storing the substrate. The transfer device 903 serves to transfer the substrate S between the main transport path 901 and a sub-transport path 902a or 902b. Referring to FIG. 10, a rail 201a which continuously extends from the inside of the tunnel 101 of the main transport path 901, and rails 201b and 201c which continuously extend from the inside of the tunnels 101 of the sub-transport paths 902a and 902b are arranged in the transfer device 903. Thus, a substrate transport car 202 which travels in the tunnel 101 of the main transport path 901 can enter and leave the transfer device 903.

Push-up tables 1001a, 1001b, and 1001c corresponding in number to the rails, and a transfer robot 1002 are also arranged in the transfer device 903. When the substrate transport car 202 which has been transported along the rail 201a, 201b, or 201c stops above the push-up table 1001aa, 1001b, or 1001c, the push-up table 1001a, 1001b, or 1001c pushes up from below the substrate S transported by the substrate transport car 202. In this state, when the substrate transport car 202 leaves, the U-shaped hand of the transfer robot 1002 enters the space below the substrate left on the push-up table 1001a, 1001b, or 1001c. When the push-up table 1001a, 1001b, or 1001c lowers, the substrate is placed on the transfer robot 1002. When the transfer robot 1002 rotates, the substrate S is placed on another push-up table, and transferred to a substrate transport car 202 on a different rail. In order to perform this transfer process smoothly, the arm of the transfer robot 1002 has joint portions at at least two portions, so that it can move the substrate S very freely.

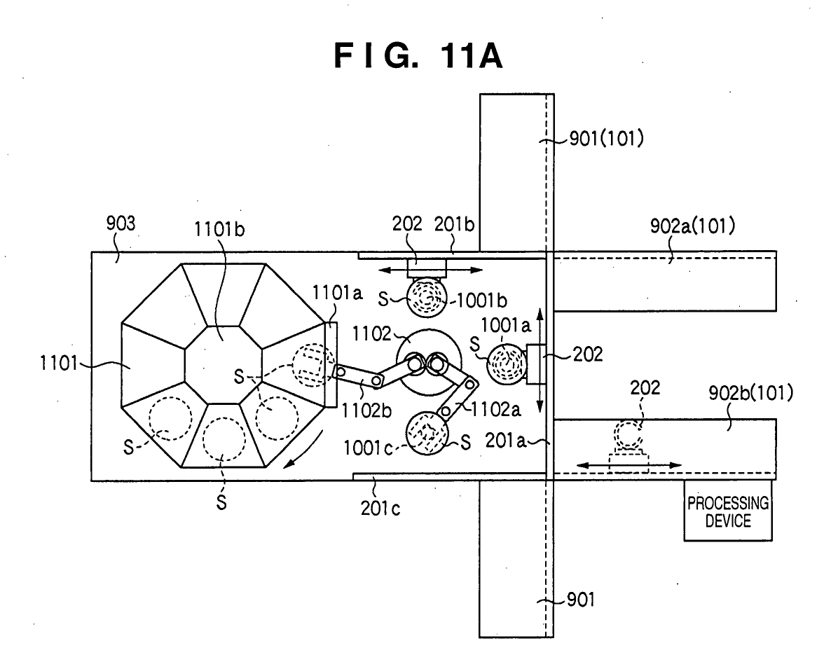

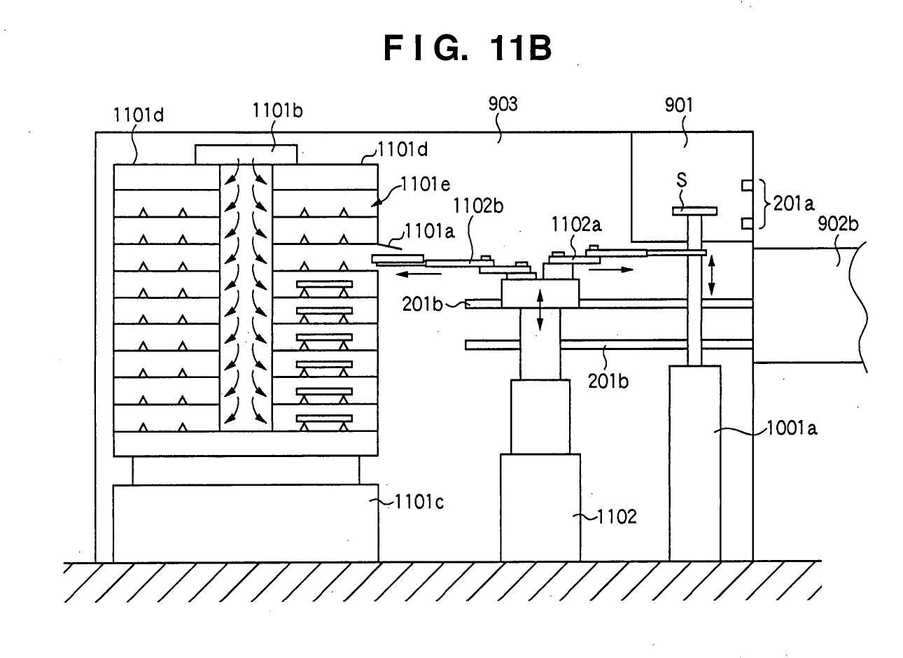

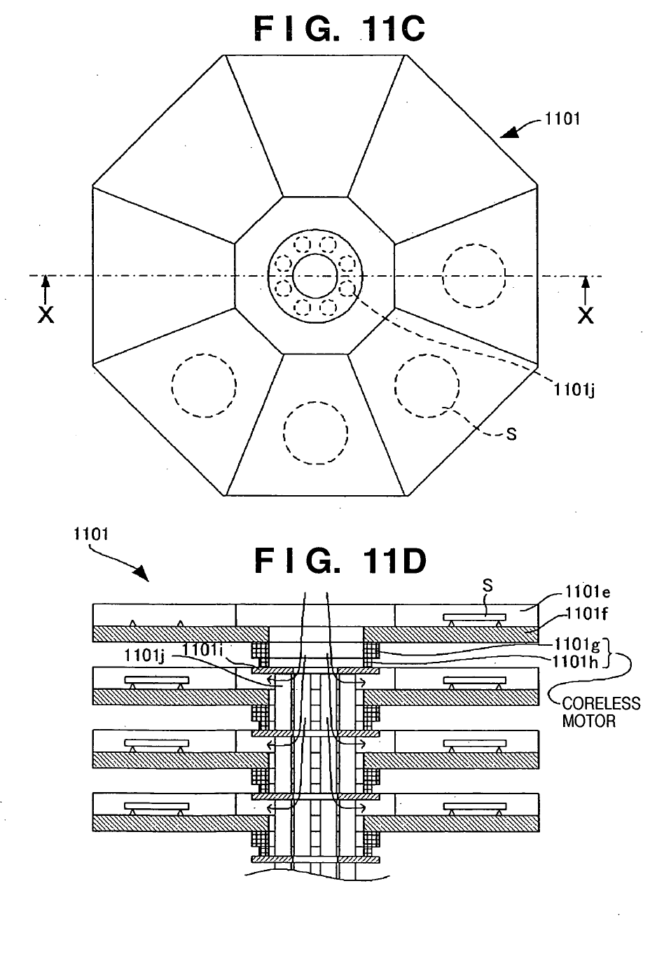

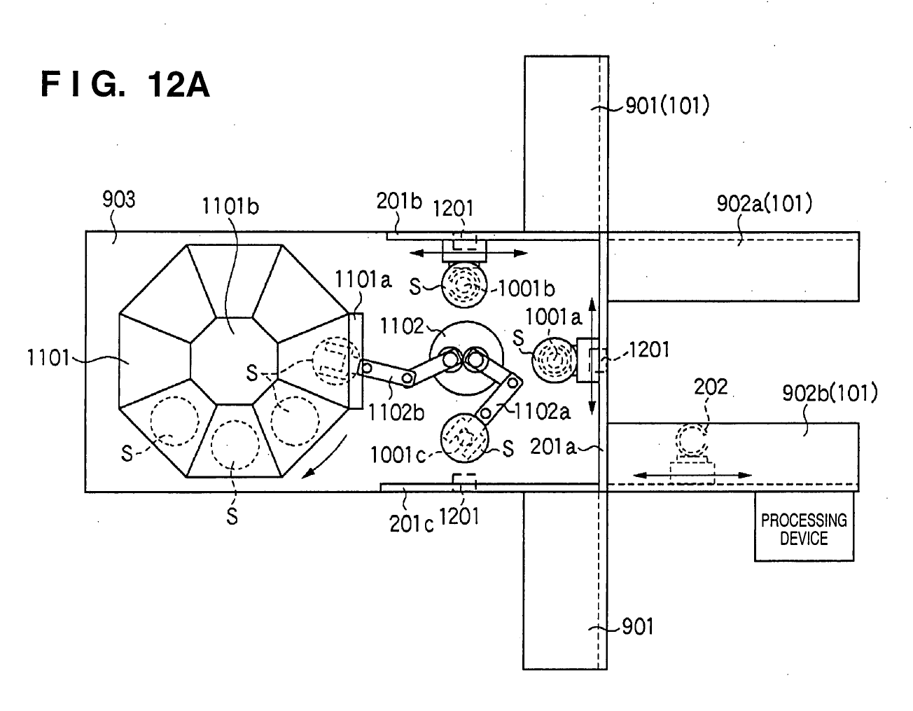

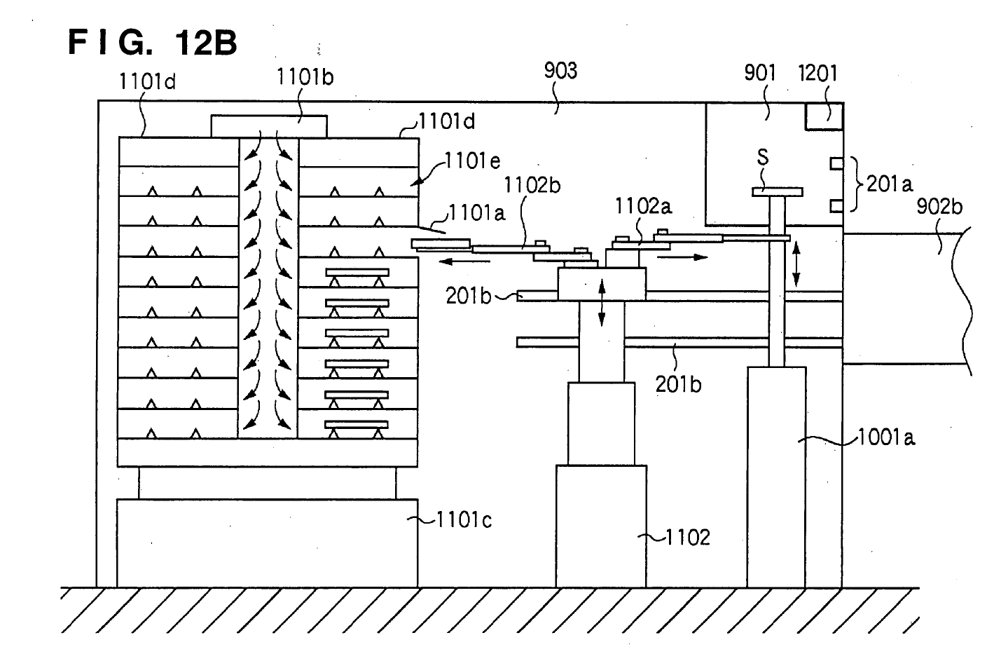

A transfer device 903 which has the function of storing the substrate will be described with reference to FIGS. 11A to 11D and FIGS. 12A and 12B. FIG. 11A is a plan view showing the internal structure of the transfer device 903 which has the function of storing the substrate, and FIG. 11B is a side sectional view of the same. The transfer device 903 serves to transfer the substrate between the main transport path 901 and a sub-transport path 902a or 902b and store the substrate. As the substrate S is stored one by one in this manner, the number of substrates which are to be transported by the sub-transport path and main transport path can be adjusted. Thus, the transfer device 903 serves as a buffer in case the processing load increases.

The transfer device 903 shown in FIGS. 11A and 11B has a stocker 1101 as well as a transfer robot 1102 having two arms 1102a and 1102b. Except for this, the structure of the transfer device 903 is the same as that shown in FIG. 10. Accordingly, the same mechanism is denoted by the same reference numeral, and a description thereof will be omitted. With the transfer device provided with the stocker 1101, the number of substrates S to be transferred increases. Hence, the transfer robot 1102 desirably has the two arms 1102a and 1102b in this manner, but a transfer robot 1102 of a type shown in FIG. 10 which has only one arm can also naturally be used. The arms 1102a and 1102b of the transfer robot 1102 serve in the same manner as the arm of the transfer robot 1002 described with reference to FIG. 10, and accordingly a description thereof will be omitted.

The stocker 1101 has the shape of an octagonal prism, and rotates as indicated by an arrow so that substrates can be inserted in eight shelves 1101d from eight surfaces. FIG. 11A shows a state wherein substrates are stored in four out of eight shelves. When a substrate S is to be inserted in the shelf, a door1101a is opened as shown in FIG. 11A. A cleaning unit 1101b is arranged at the center of the upper surfaces of the eight shelves, and blows off clean air downward as indicated by arrows. Another cleaning unit may also be provided on the transfer device 903.

As shown in FIG. 11B, in each of the eight shelves 1101d, a plurality of substrate storage rooms 1101e pile up vertically. A stocker rotating device 1101c is provided under the eight shelves to rotate the entire stocker 1101 clockwise or counterclockwise.

To be able to transport the substrates to the respective substrate storage rooms 1101e that are continuous vertically, the transfer robot 1102 can move vertically as well. In this case, in place of the push-up tables 1001, tables that are vertically immobile can be used. Alternatively, the transfer robot 1102 can receive the substrate S from the substrate transport car 202 directly. To be able to receive the substrate S from the substrate transport car 202 directly, the hands formed at the distal ends of the arms 1102a and 1102b of the transfer robot 1102 must have shapes that conform to the tray shape of the substrate transport car 202.

As shown in FIG. 11B, the main transport path 901 and sub-transport path 902 are desirably shifted from each other vertically so their rails do not come into contact with each other. Although the stocker 1101 is described as one that stores the substrates, a stocker that stores reticles can be implemented by completely the same structure. The substrates and reticles can be stored in one stocker. The shape of the stocker is not limited to an octagonal prism but can be a cylinder. A flat shelf that does not rotate can be used as a stocker if the transfer robot 1102 has a mechanism that moves vertically and horizontally.

FIG. 11C is a plan view for explaining another example of the stocker 1101, and FIG. 11D is a partial sectional view taken along X-X of FIG. 11C. In the example shown in FIGS. 11C and 11D, a plurality of substrate storage rooms 1101e are formed on respective annular tables 1101f, and the tables 1101f are supported at their central portions by respective coreless motors. Thus, the substrate storage room 1101e of each stage is integrally movable. The entire stocker 1101 has a multilayer structure in which the tables 1101f and coreless motors pile up vertically. This will be described in detail. Each coreless motor includes an annular rotary portion 1101g and annular stationary portion 1101h. The rotary portion 1101g can rotate relative to the stationary portion 1101h. The lower surface of the table 1101f is fixed to the upper surface of the rotary portion 1101g, and the lower surface of the stationary portion 1101h is fixed to the upper surface of a stationary member 1101i. The stationary members 1101i of the respective stages are connected to each other through a plurality of cylindrical support members 1101j to form a coreless tower as a whole. A cleaning unit (not shown) is provided above the coreless portion located at the center of the stocker 1101, and blows off clean air downward as indicated by arrows.

As the motors are provided to the respective stages in this manner, the loads to the respective motors can be decreased, so that the motors can rotate and stop accurately at a high speed. The operation of storing and replacing the reticles, substrates, or the like in the stocker 1101 can be performed efficiently. The reticles and substrates can be separately stored in the separate stages, so that they can be managed easily.

FIGS. 12A and 12B are views for describing a transfer device 903 which has reading devices 1201 for reading information on the substrate. The transfer device 903 shown in FIGS. 12A and 12B has the reading devices 1201, which read information added to the reticle, substrate, or the like, above respective push-up tables 1001a, 1001b, and 1001c. Except for this, the structure of the transfer device 903 is the same as that of the transfer device 903 shown in FIGS. 11A and 11B. Thus, the same mechanism is denoted by the same reference numeral, and a description thereof will be omitted.

Each reading device 1201 reads information added to the reticle, substrate, or the like and transmits storage information on the reticle, substrate, or the like stored in a stocker 1101 to an information management device (not shown). Hence, the number of substrates or reticles in the stocker 1101 can be managed. On the basis of the information from the information management device, a reticle or substrate corresponding to the request from each processing device 102 is extracted from the stocker 1101 and transported to a target processing device. While the reading devices 1201 are arranged above the push-up tables 1001a, 1001b, and 1001c, they may be arranged in substrate storage rooms 1101le of the stocker 1101. If information is managed by using a wireless communication IC memory (wireless IC tag), information on a plurality of reticles, substrates, or the like can be communicated at once, so that information on the reticles, substrates, or the like in the stocker 1101 can be managed real time.

In the above embodiment, one stocker is contained in the transfer device. Alternatively, a plurality of stockers may be contained in the transfer device.

### Effect of This Embodiment

As described above, according to this embodiment, as the substrates or the like are transported individually in the tunnel, the environment around the substrates or the like can be cleaned at high accuracy, and accordingly the substrate processing accuracy improves. Since the interface devices are made versatile to cope with various processing devices, a large number of interface devices need not be prepared to match the respective processing devices, and the facility cost of the system as a whole can be reduced. When the interface devices are arranged below the tunnel, various processing devices having substrate loading ports at different heights can be coped with by only changing the positions to install the interface devices. Thus, the system can become more versatile. Since substrate delivery between the tunnel as the transport path and the interface device is realized by a push-up mechanism, the substrate can be delivered to and from an interface device set at any height by only changing the push-up stroke. Thus, the system can become more versatile. If an orientation fracture alignment mechanism is built in the push-up mechanism, the apparatus can be made further compact. Since the interface device can include a chamber that can deal with a vacuum, a pressure switching device for switching the pressure need not be additionally provided. The facility installation area can be used effectively, so that the facility cost can be reduced greatly.

Since the plurality of substrate transport cars travel in one tunnel in a multiple manner, the respective substrate transport cars can travel in two directions independently of each other, and can overtake each other. Thus, the substrates can be transported without congestion.

### Second Embodiment

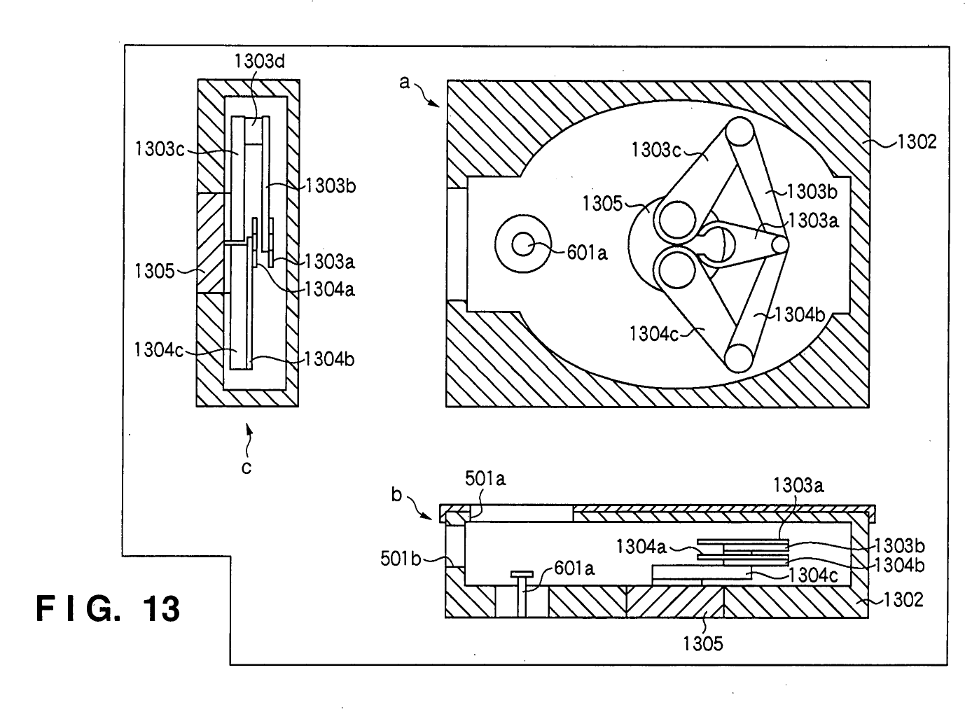

An interface device according to the second embodiment of the present invention will be described with reference to FIGS. 13 to 18. The interface device according to this embodiment is different from that of the first embodiment in that it has a robot arm in its chamber 1302. Except for this, the structure of the second embodiment is the same as that of the first embodiment. Accordingly, the same structure is denoted by the same reference numeral, and a detailed description thereof will be omitted.

FIGS. 13 to 18 are views showing the interior of the chamber 1302 of an interface device 103 according to this embodiment, in which a of each of FIGS. 13 to 18 is a plan view of the interior of the chamber 1302, and b of the same is a front view of the interior of the chamber 1302. Also, c of FIG. 13 is a left side view of the interior of the chamber 1302. For the sake of descriptive convenience, in FIGS. 13 to 18, the wall surface portion of the chamber 1302 is shown by a section. Two robot arms 1303 and 1304 are arranged in the chamber 1302, and are pivotally supported by an arm table 1305 arranged on the bottom portion of the chamber 1302.

The robot arms 1303 and 1304 respectively have hands 1303a and 1304a which place substrates. The hands 1303a and 1304a have fork-like distal end portions each similar to a tray 202a of a substrate transport car. The gap of the opening of the distal end portion is wider than the diameter of a push-up rod 601a. Each of the hands 1303a and 1304a is pivotally connected to one end of the corresponding one of first arm portions 1303b and 1304b. The other end of each of the first arm portions 1303b and 1304b is pivotally connected to the corresponding one of second arm portions 1303c and 1304c. Furthermore, the other end of each of the second arm portions 1303c and 1304c is pivotally connected to the arm table 1305. As shown in c of FIG. 13, a cylindrical spacer 1303d is provided to the connecting portion of the first arm portions 1303b and 1303c, and accordingly the first arm portions 1303b and 1304b have different heights. Hence, the hands 1303a and 1304a do not collide against each other but can move freely in the horizontal direction. FIG. 13 shows a state wherein both the robot arms 1303 and 1304 stand by at the basic position. At the basic position, the hands 1303a and 1304a are located at the same position in the horizontal direction. Thus, a of FIG. 13 shows only the upper hand 1303a.

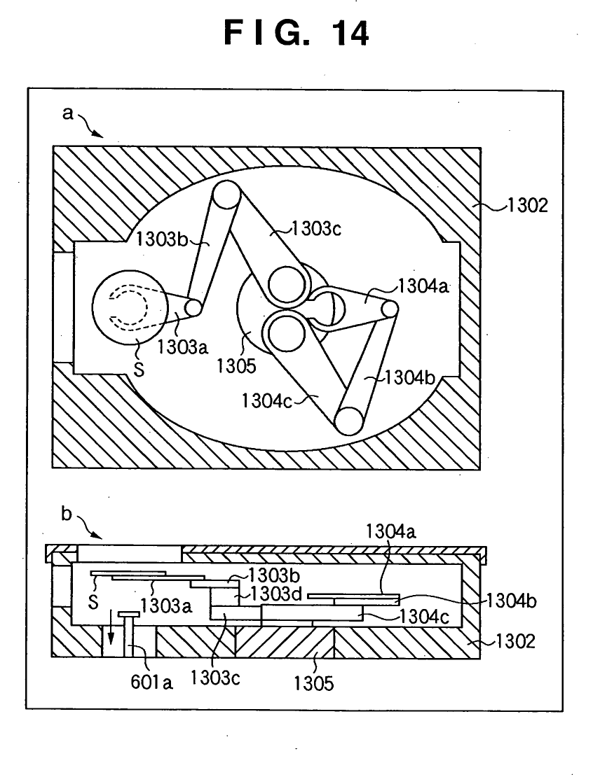

FIG. 14 shows a state wherein the interface device 103 according to this embodiment receives a substrate S from a tunnel 101. The process from receiving the substrate from a substrate transport car 202 which travels in the tunnel 101 to placing it on the hand 1303a is substantially the same as in the first embodiment. More specifically, the substrate transport car 202 on which the substrate S is placed travels along a rail 201 and stops on the upper portion of the interface device 103. Subsequently, a shutter 204 in the lower portion of the tunnel 101 and a gate valve 502 on the upper portion of the interface open. A substrate elevating unit 601 operates to move the push-up rod 601a upward so as to push up the substrate S on the tray 202a of the substrate transport car 202.

When the push-up operation of the substrate S is completed, the substrate transport car 202 is moved so that the push-up rod 601a extends through a gap G of the tray 202a. When the substrate transport car 202 completely retreats from the substrate delivery position, the substrate elevating unit 601 operates to move the push-up rod 601a downward with the substrate S being placed on it. Simultaneously, the respective joints of the robot arm 1303 are driven to move the hand 1303a so that the push-up rod 601a enters the fork-like opening formed at the distal end of the hand 1303a.

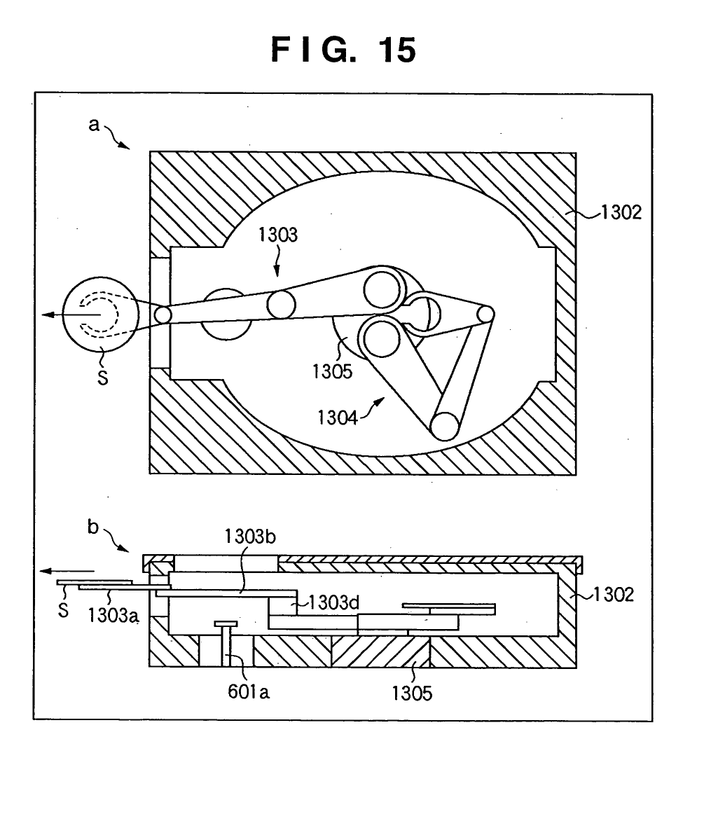

The push-up rod 601a on which the substrate S is placed stops temporarily before the substrate S reaches the hand 1303a, rotates the substrate S at the position to align the orientation fracture. When the orientation fracture alignment is ended, the push-up rod 601a is further moved downward to place the substrate S on the hand 1303a, as shown in FIG. 14. Then, the shutter 204 in the lower portion of the tunnel 101 and the gate valve 502 on the upper portion of the interface are closed. After that, the internal pressure of the interface device 103 is set to coincide with the pressure of a processing device 102. Subsequently, a gate valve 503 on the processing device 102 side is opened to project the robot arm 1303 toward the processing device 102, as shown in FIG. 15. When the processing device 102 receives the substrate S placed on the hand 1303a of the robot arm 1303, the robot arm 1303 is retreated to the basic position shown in FIG. 13. Then, the gate valve 503 is closed to restore the pressure in a chamber 501 to an atmospheric pressure.

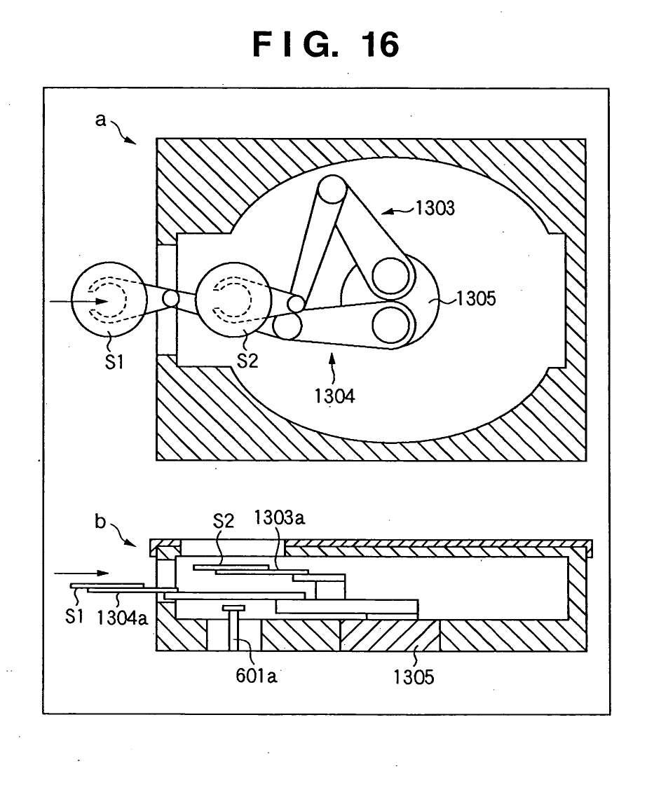

The substrate S is then received from the substrate transport car 202 again with completely the same procedure as that described above, to switch to the state of FIG. 14. In the state of FIG. 14, the lower robot arm 1304 is stretched toward the processing device 102 to switch to the state of FIG. 16, so as to receive a processed substrate S1 from the processing device 102. In FIG. 16, an unprocessed substrate placed on the upper robot arm 1303 is defined as a substrate S2.

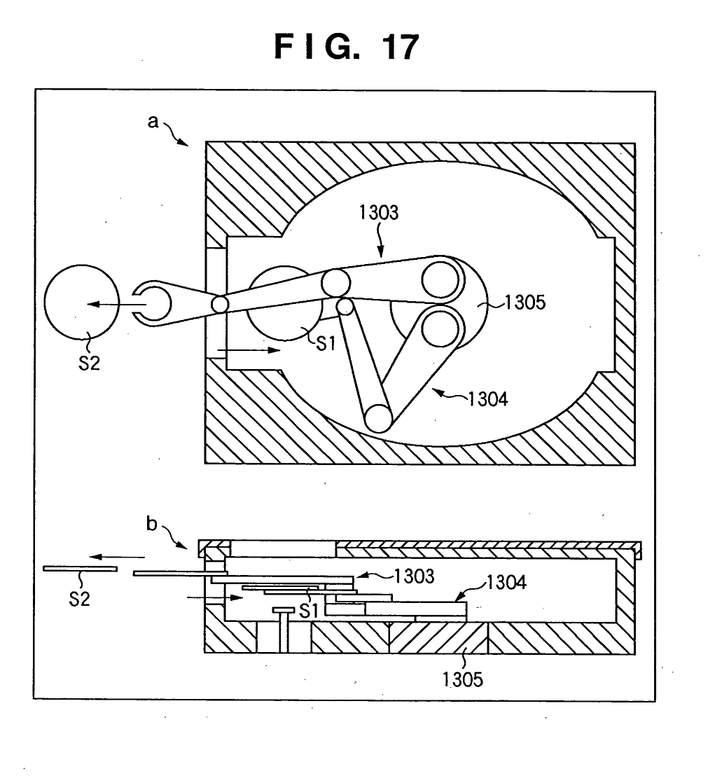

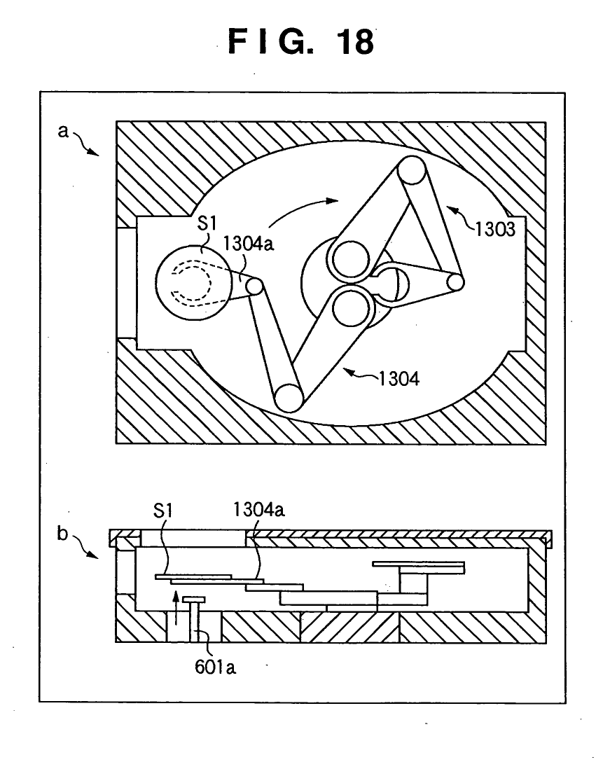

While the lower robot arm 1304 is being retreated, the upper robot arm 1303 is stretched as a replacement toward the processing device 102 to switch to the state of FIG. 17. When the processing device 102 receives the unprocessed substrate S2 placed on the hand 1303a of the robot arm 1303, the robot arm 1303 is retreated to the home position, as shown in FIG. 18, and the gate valve 503 is closed to restore the pressure in the chamber 501 to the atmospheric pressure. After that, a substrate unloading request is sent to the substrate transport car 202. The substrate transport car 202 is made to stand by before the substrate receiving position above the interface device 103, and the shutter 204 and gate valve 502 are opened. Subsequently, the push-up rod 601a moves upward to push up the substrate S1 on the hand 1304a, moves further upward, and stops. The substrate transport car 202 which has been standing by at the standby position is moved so that the push-up rod 601a extends through the gap G of the substrate transport car 202. In this state, the push-up rod 601a moves downward to place the substrate S1 onto the tray 202a of the substrate transport car 202. After the downward movement of the push-up rod 601a is completed, the substrate transport car 202 transports the substrate S1 to the next processing device. Simultaneously, the shutter 204 and gate valve 502 are closed.

After that, the robot arm 1304 is returned to the basic position shown in FIG. 13 again. The robot arms 1303 and 1304, push-up rod 601a, substrate transport car 202, shutter 204, gate valves 502 and 503, a pump 801, and the like are operated so that a series of state changes of FIG. 14→FIG. 16→FIG. 17→FIG. 18→FIG. 13 is repeated.

As described above, when the two-stage robot arms are used, an unprocessed substrate can be loaded into the processing device 102 and a processed substrate can be unloaded from the processing device 102 simultaneously. When compared to a case wherein a processed substrate is set on the substrate transport car and thereafter the next unprocessed substrate is loaded, the substrate process can be performed remarkably quickly.

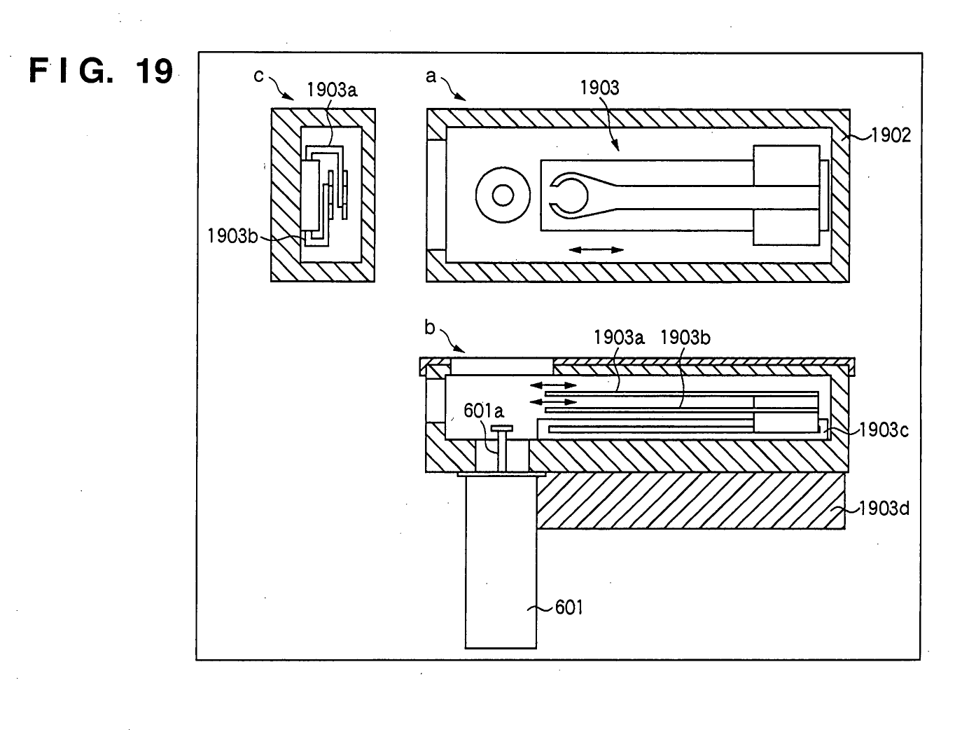

FIG. 19 shows a modification of this embodiment. FIG. 19 is a view showing the interior of a chamber 1902 of the interface device 103 in the same manner as in FIG. 13, in which a is a plan view of the interior of the chamber 1902, and b is a front view of the interior of the chamber 1902 c is a left side view of the interior of the chamber 1902. For the sake of descriptive convenience, in FIG. 19, the wall surface portion of the chamber 1902 is shown by a section.

A slide unit 1903 including two slide arms 1903a and 1903b is provided in the chamber 1902. The slide unit 1903 includes a slide table 1903c and slider drive 1903d. Power from the slider drive 1903d reciprocally moves the slide arms 1903a and 1903b attached to the slide table 1903c horizontally in the direction of arrows.

The slide arms 1903a and 1903b have fork-like distal end portions in the same manner as the robot arms described above. The gap of the opening of the distal end portion is wider than the diameter of a push-up rod 601a. The slide arms 1903a and 1903b are slidably connected to the two side surfaces of the slide table 1903c, and supported by arms having different shapes so they have different heights, as shown in c of FIG. 19. Hence, the slide arms 1903a and 1903b do not collide against each other but can slide freely in the horizontal direction. FIG. 19 shows a state wherein both the slide arms 1903a and 1903b stand by at the basic position. At the basic position, the distal ends of the slide arms 1903a and 1903b have retreated in a direction opposite to the processing device 102, in the same manner as in the first embodiment, so that the push-up rod 601a on which the substrate is placed can vertically move freely.

In the interface device 103 shown in FIG. 19 as well, when a process similar to that described with reference to FIGS. 13 to 18 is performed, while a processed substrate is being unloaded by one slide arm, an unprocessed substrate can be loaded into the processing device 102 by the other slide arm. Thus, the substrate processing speed can increase in the same manner as that described above.

Furthermore, the slide arms 1903a and 1903b shown in FIG. 19 can have built-in multi-stage slide mechanisms. In this case, the slide arms not only slide but also become stretchable. Thus, the interface device 103 can be downsized in the widthwise direction of FIG. 19.

### Third Embodiment

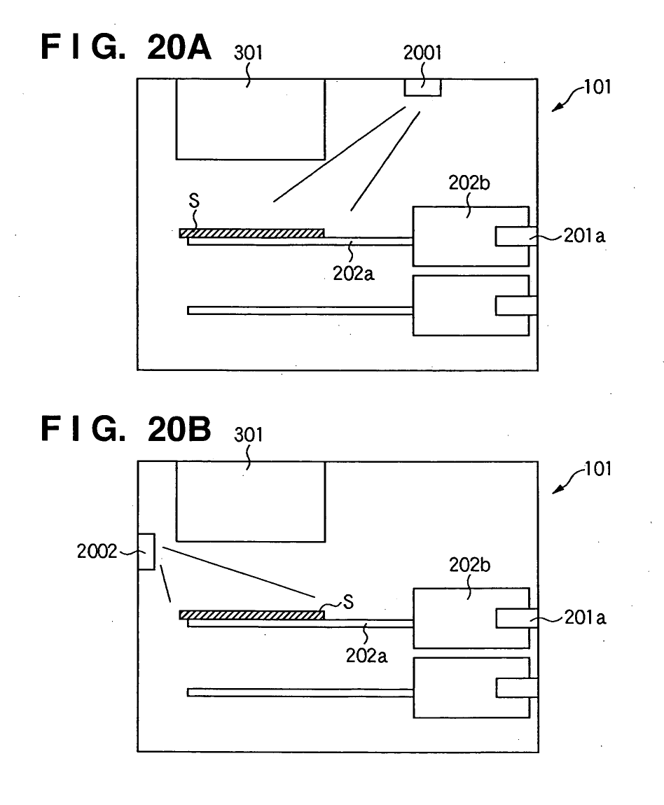

A tunnel 101 according to the third embodiment of the present invention will be described with reference to FIGS. 20A and 20B. The tunnel 101 according to this embodiment is different from that of the first embodiment in that it has a reading device to read information added to the substrate. Except for this, the structure and operation of the third embodiment are the same as those of the first embodiment. Accordingly, the same structure is denoted by the same reference numeral, and a description thereof will be omitted.

FIGS. 20A and 20B are schematic views showing only the internal structure of the tunnel 101, which corresponds to the tunnel portion of FIG. 2A. In FIG. 20A, a reading device 2001 is provided to the ceiling portion of the tunnel 101. In FIG. 20B, a reading device 2002 is provided to the side wall of the tunnel 101. The reading device 2001 or 2002 is a reading device to read information recorded on a substrate S to be transported. The reading device 2001 or 2002 may be a barcode reading device if, e.g., a barcode is printed on the substrate S. If a wireless communication IC memory (wireless IC tag) is buried in or added to the substrate S or if an ID tag is added to the substrate S, the reading device 2001 or 2002 may be a receiving device to receive data transmitted from the wireless communication IC memory (wireless IC tag) or ID tag. The reading device 2001 or 2002 can be a character recognition sensor which reads a character recorded on the surface of the substrate S. The wireless communication IC memory (wireless IC tag) is a storage device which includes an antenna to transmit and receive data in an IC microchip. The wireless communication IC memory is operated by the radio waves with a predetermined frequency transmitted from the reading device to transmit and receive the data.

While a case has been described wherein the reading device which reads data from an IC tag or ID tag is provided to the tunnel, the reading device may have the function of writing data on an IC tag or the like added to a substrate. In this case, for example, information representing a processing device which has completed the process for the substrate is written on the substrate. Feedback control or feed-forward control is performed on the basis of the processing information to transport the substrate, thus further facilitating substrate transportation control. Furthermore, in place of the reading device, a writing device which writes data on an IC tag or the like added to a substrate may be provided. While a device has been described which reads and writes data on and from the substrate in a noncontact manner, a contact type reading or writing device can naturally be used instead.

### Fourth Embodiment

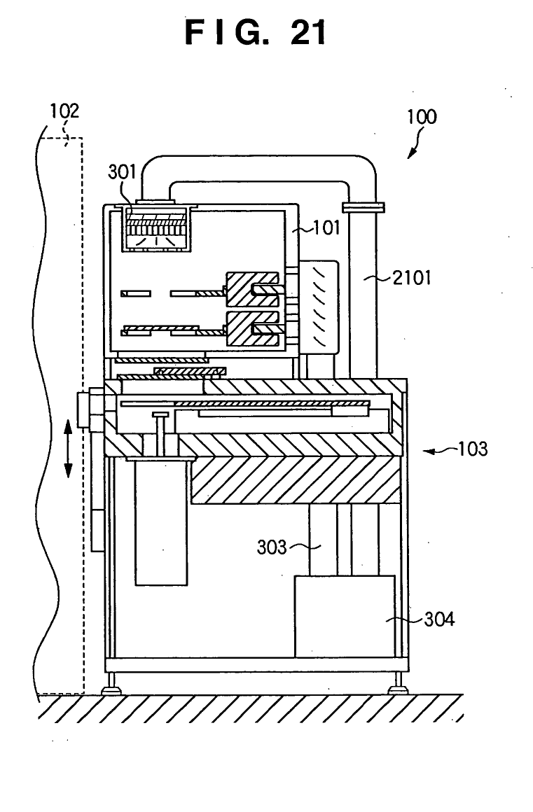

A tunnel 101 according to the fourth embodiment of the present invention will be described with reference to FIG. 21. The tunnel 101 according to this embodiment is different from that of the first embodiment in that it performs self circulation type cleaning. Except for this, the structure and operation of the tunnel 101 are the same as those of the first embodiment. Accordingly, the same structure is denoted by the same reference numerals, and a description thereof will be omitted.

FIG. 21 is a schematic view showing the interior of the tunnel 101 and that of an interface device 103. As shown in FIG. 21, in this system 100, an air discharge unit 304 has a built-in pump function. Air discharged from the air discharge unit 304 is fed to the cleaning units 301 again through a pipe 2101. Thus, self-circulation type air cleaning can be realized. When compared to a case wherein a pipe is laid to extend along the tunnel 101, the entire facility can be simplified, and the independence of each unit of the tunnel 101 increases, so that maintenance becomes easy.

### Fifth Embodiment

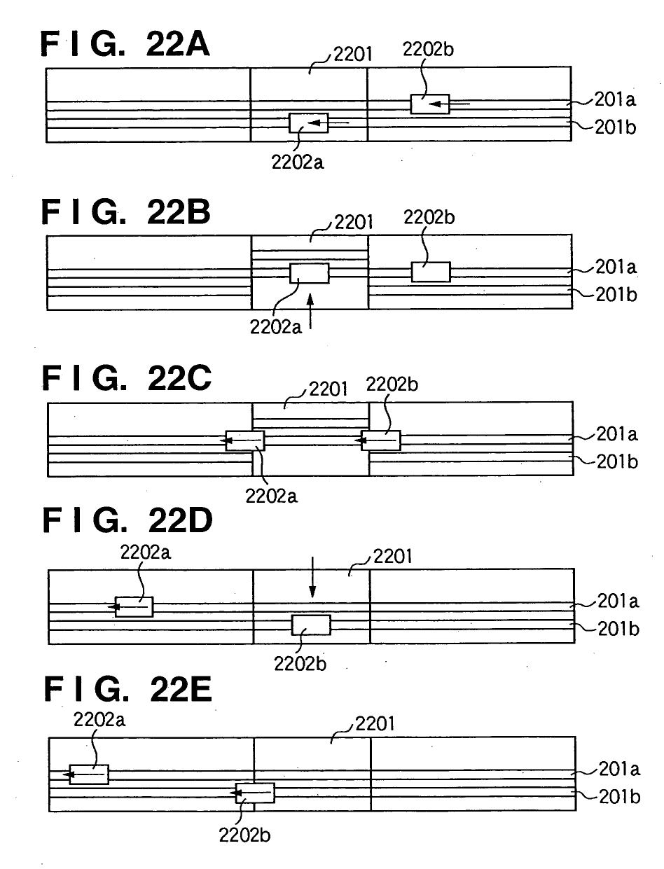

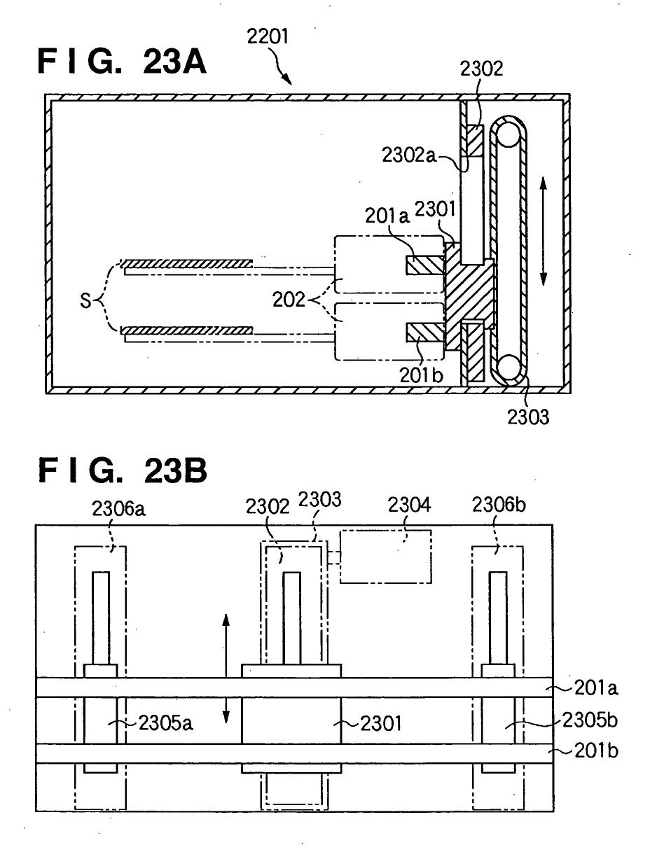

A tunnel 101 according to the fifth embodiment of the present invention will be described with reference to FIGS. 22A to 23B. A system 100 according to this embodiment has a means for switching the transport path in the tunnel. More specifically, the fifth embodiment is different from the first embodiment in that the system 100 forms one unit to provide a tunnel unit having a rail switching mechanism. Except for this, the structure and operation are the same as those of the first embodiment. Accordingly, the same structure is denoted by the same reference numeral, and a detailed description thereof will be omitted.

FIGS. 22A to 22E are views for explaining the rail switching operation. First, assume that a substrate transport car 2202a traveling along a lower rail 201b is to be shifted to an upper rail 201a. As shown in FIG. 22A, the substrate transport car 2202a is stopped in a tunnel unit 2201 having a rail switching function. Subsequently, as shown in FIG. 22B, the rails in the tunnel unit 2201 are slid upward. Then, as shown in FIG. 22C, the substrate transport car 2202a is caused to travel. Assume that a substrate transport car 2202b traveling along the upper rail 201a is to be shifted to the lower rail 201b. In the state shown in FIG. 22C, the substrate transport car 2202b is stopped in the tunnel unit 2201. As shown in FIG. 22D, the rails are slid downward. Then, as shown in FIG. 22E, the substrate transport car 2202b is caused to travel.

FIGS. 23A and 23B are views for explaining a rail slide mechanism in the tunnel unit 2201. FIG. 23A is a schematic view of the tunnel seen from the longitudinal direction, and FIG. 23B is a schematic view of the tunnel seen from the left side in FIG. 23A. Referring to FIGS. 23A and 23B, both the rails 201a and 201b are fixed to a rail support member 2301. The rail support member 2301 extends in a groove 2302a of a guide member 2302 and is fixed to a belt 2303. The belt 2303 can be vertically reciprocated by a motor 2304. On the two sides of the support member 2301, the rails 201a and 201b are fixed to auxiliary support members 2305a and 2305b. The auxiliary support members 2305a and 2305b are slidable along grooves in auxiliary guide members 2306a and 2306b.

In this structure, when the motor 2304 is driven, the rail support member 2301 vertically moves together with the belt 2303. The rails 201a and 201b vertically slide while maintaining the gap between them.

In this embodiment, the rail pair is slid by using the motor 2304 and belt 2303, but the present invention is not limited to this. For example, the rail pair may be slid by another mechanism such as a wire takeup mechanism or pressure cylinder.

### Other Embodiment

In the above embodiment, two rails are provided in the tunnel, but the number of rails in the tunnel is not limited to this, but can be three or more, or one.

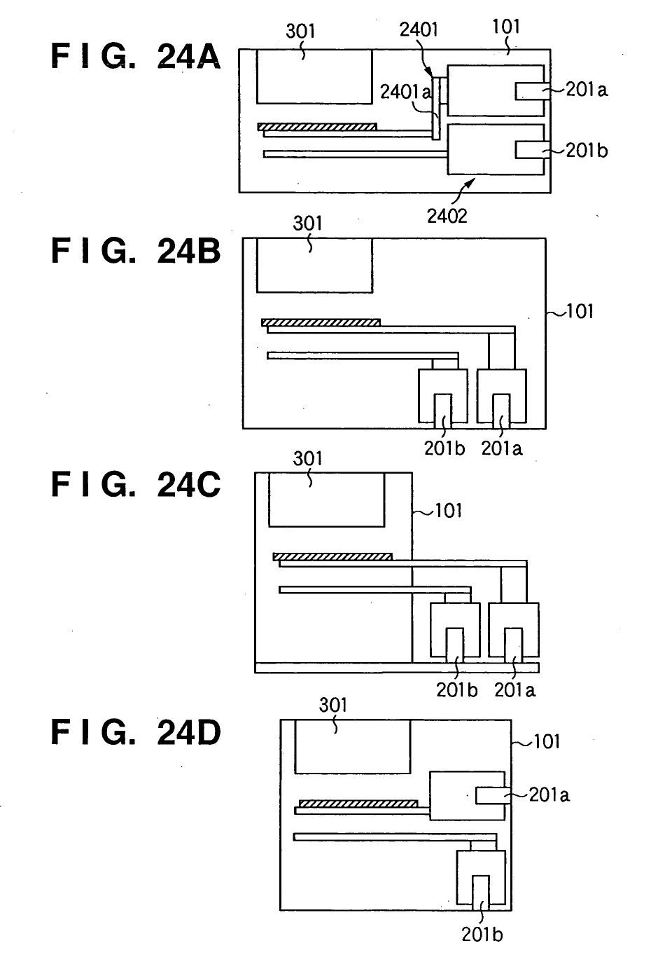

The layout in the tunnel is not limited to that shown in the first embodiment. For example, as shown in FIG. 24A, a substrate transport car 2401 which travels along an upper rail 201a and a substrate transport car 402 which travels along a lower rail 201b may have different structures. More specifically, a tray 2401a of the substrate transport car 2401 which travels along the upper rail 201a may have an L-letter shape to decrease the distance to a tray 2402a of the lower substrate transport car 2402. Then, the ceiling of the tunnel can be lowered, and the structure of the tunnel as a whole can be made compact.

As shown in FIG. 24B, rails 201a and 201b may be laid on the bottom portion of the tunnel. In this case, a substrate transport car 2401 which travels along the rail 201a and a substrate transport car 2402 which travels along the rail 201b must have different structures so that the respective trays travel to maintain a vertical gap between them. Then, when compared to a case wherein rails are provided to the tunnel side wall, a bending stress does not easily occur to the rails, so that the substrate transport cars can travel comparatively stably.

Furthermore, as shown in FIG. 24C, rails 201a and 201b may be laid to extend outside the tunnel, and only the trays of the substrate transport cars may be accommodated in the tunnel. Then, dust which is raised as the substrate transport cars travel does not attach to the substrate, and the environment where the substrate travels can be made very clean. Also, as shown in FIG. 24D, a rail 201a may be laid on the tunnel side wall, and a rail 201b may be laid on the tunnel bottom portion. While the air cleaning unit is set on the tunnel ceiling portion, it may be set on either tunnel side wall.

In the above embodiments, a structure has been described in which the slide unit can move the substrate only horizontally in the chamber, but the present invention is not limited to this. For example, the robot or slide unit may be further provided with an elevating mechanism which can move the substrate vertically. In this case, the substrate can be moved vertically to the substrate loading ports of the plurality of types of processing devices. While the processing device stands by at its delivery position to deliver the substrate, the substrate can be delivered to a table (not shown) of the processing device.

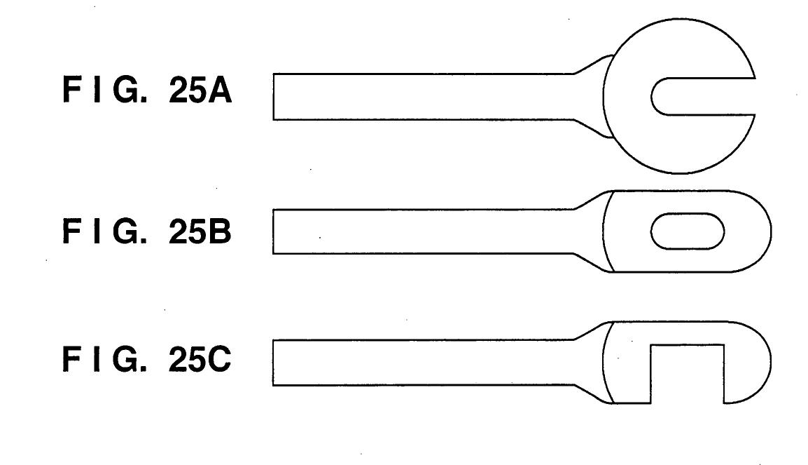

In the above embodiments, as an arm which transports the substrate to the processing device in the interface device, one having a U-shaped fork-like hand at its distal end is shown, but the present invention is not limited to this. For example, various types of hands as shown in FIGS. 25A to 25C can be employed. More specifically, FIG. 25A shows a C-shaped hand having a circular distal end, FIG. 25B shows an O-shaped hand having a hole in which a push-up rod is to be inserted, and FIG. 25C shows a U-shaped hand which opens sideways to the processing device. These hand portions can be made detachable so that they can be exchanged in accordance with the types of the processing devices.

When processing devices are arranged on the two sides of the tunnel, openings may be formed in the two side surfaces of each interface device, and one transporting means can be moved toward and away from the processing devices on the two sides. In particular, if the substrates are to be transported to the processing devices on the two sides by using robots, the space where the facilities are installed can be utilized more effectively.

In the structure of the above embodiment, power is supplied from the feeding elements 203 to the substrate transport cars 202, and the substrate transport cars 202 are transported on the rails by the motors in the substrate transport cars 202. However, the present invention is not limited to this structure. A structure in which the substrate transport cars are levitated and transported by air or magnetism is also incorporated in the present invention.

According to the present invention, a versatile substrate transportation system can be provided which can cope with various processing devices with high degrees of freedom.

The present invention is not limited to the above embodiments and various changes and modifications can be made without departing from the spirit and scope of the present invention. Therefore, to apprise the public of the scope of the present invention, the following claims are made.

What is claimed is:

1. A substrate transportation system comprising:
a tunnel which transports a substrate one by one;
air circulating means for exhausting air in said tunnel and returning air to said tunnel; and
a cleaning unit for cleaning air returned to said tunnel by said air circulating means.

2. The substrate transportation system according to claim 1, wherein said cleaning unit includes a HEPA filter or an ULPA filter.

3. The substrate transportation system according to claim 2, wherein said HEPA filter or said ULPA filter is detachably attached to said tunnel.
